(19) United States
(12) Patent Application Publication
(10) Pub. No.: US 2009/0243693 A1
(43) Pub. Date: Oct. 1, 2009

(54) CIRCUIT FOR PROVIDING DETERMINISTIC LOGIC LEVEL IN OUTPUT CIRCUIT WHEN A POWER SUPPLY IS GROUNDED

(76) Inventors: Meetul GOYAL, El Dorado Hills, CA (US); Robert James Johnston, Sacramento, CA (US); Romesh Trivedi, Folsom, CA (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/058,802

(22) Filed: Mar. 31, 2008

(51) Int. Cl. H03L 5/00

(52) U.S. Cl. 327/333

(57) ABSTRACT

A high voltage analog interface circuit capable of producing a determinate zero or other low voltage when the high voltage power supply is turned off or grounded.

### TECHNICAL FIELD

Embodiments of the present invention relate generally to data transfer electronic circuits, and more particularly to an input-output buffer circuit for a high voltage signal.

### BACKGROUND

A high voltage analog interface may use two power rails having different voltages. One such example is Intel High Definition (IHD) Audio, also known as “Azalia”, which provides a high voltage analog interface for delivering high-definition audio using two power rails on Intel Corporation Graphics and Memory Controller Hub (GMCH). The GMCH may be, for example, a northbridge chip in the core logic chipset on a PC motherboard. The GMCH may typically handle communications between the Central Processing Unit (CPU), Random Access Memory (RAM), Accelerated Graphic Port (AGP) or Peripheral Component Interconnect (PCI) Express, and another chip in the core logic chipset, for example, the Input/Output (I/O) controller hub, or southbridge, and may also include an integrated video controller and/or an integrated audio controller.

In certain versions of the GMCH, it may be desirable to disable the logic unit, which will disable the corresponding feature, residing in the GMCH core, with which the high voltage analog interface interacts; however, the common option of using a fuse to enable/disable the unit may not be available or desirable. In some GMCH cores, in order to disable the unit or feature, the high voltage analog interface may require sending logic “0” on the reset pin. The GMCH units and/or parts where the unit or feature is disabled have the high voltage power rail tied to ground. However, when the high voltage power rail is unavailable, certain nodes in the circuit may be caused to float to indeterminate voltage levels.

A fuse may be used to disable the input buffer and determine the state of the signal into the core when the unit or feature is disabled, but such solution is unsatisfactory for a number of reasons. The fuse adds significant area on the chip, and the programming cost of the fuse may also be unsuitable for implementation.

### BRIEF DESCRIPTION OF THE DRAWINGS

Embodiments of the present invention are described hereinafter with reference to the drawings in which:

FIG. 1 is a block level diagram of an input buffer of a high voltage analog interface unit according to embodiments of the present invention;

FIG. 2 is a schematic circuit diagram of a voltage buffer generator according to embodiments of the present invention; and

FIG. 3 is a schematic circuit diagram of an input buffer according to embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS OF THE INVENTION

In the following detailed description, numerous specific details are set forth in order to provide a thorough understanding of embodiments of the invention. However it will be understood by those of ordinary skill in the art that the embodiments of the invention may be practiced without these specific details. In other instances, well-known methods, procedures, components and circuits have not been described in detail so as not to obscure the embodiments of the invention. “Transistors”, in the context of the present specification include Field Effect Transistors (FET), and may include “terminals” such as, for example, “gate”, “source” and “drain” connectors

Some portions of the detailed description which follow are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

The desired circuit schematics of embodiments of the present invention will appear from the description below. Embodiments of the present invention may include switches, transistors or other components for obtaining output signals based on various input signals. While particular types of transistors or specific semiconductor configurations or technologies are depicted in the diagrams below, for example transistors manufactured using the complementary metal oxide semiconductor (CMOS) fabrication process, it will be understood that the novel and inventive principles of the present invention may be applied to transistors manufactured using other processes, for example, single-channel NMOS fabrication process, etc. Likewise, it will be understood that the logical operations performed on the signals may be performed may be implemented using a variety of transistor arrangements according to principles of the present invention.

Unless explicitly stated, the method embodiments described herein are not constrained to a particular order or sequence. Additionally, some of the described method embodiments or elements thereof can occur or be performed at the same point in time.

According to embodiments of the present invention, an input buffer for a high voltage analog interface circuit may be provided to produce a determinate output level even when the power supply to the analog interface circuit is turned off or grounded. Circuits according to embodiments of the invention may enable certain features, for example, a sleep mode or shutdown procedure, while saving in power consumption. In some embodiments of the invention, an analog interface circuit may use a separate, isolated power supply as a logical input to disable the circuit when the power supply is turned off or grounded. Embodiments of the present invention may thereby enable grounding of the power supply and yet permit desired shutdown of the corresponding circuit.

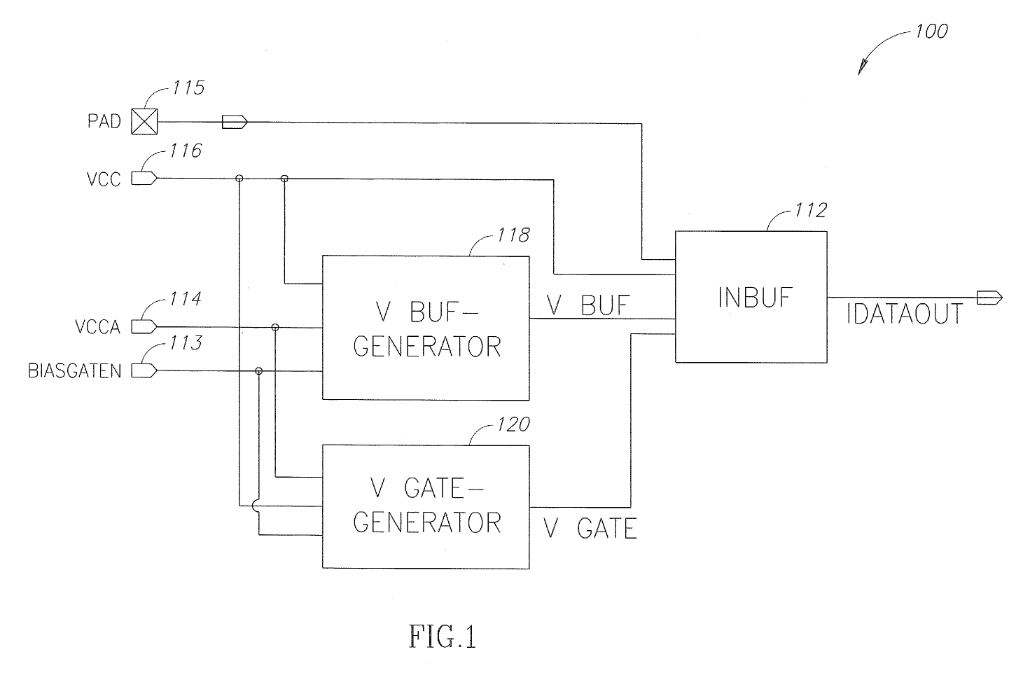

FIG. 1 depicts a general block diagram of a high voltage analog interface input buffer circuit 100 according to embodiments of the present invention. The interface may receive a power supply input Vcc voltage 116, which may be the chip voltage for the chip generally, or other power supply and an isolated voltage Vcca 114, which may be a voltage specific to the analog interface. Vcca 114 may provide a separate independent and different voltage than Vcc. In some embodiments of the invention, Vcc may be a lower voltage than Vcca. In some embodiments of the invention, Vcc may be, for example, substantially 1.25V, and Vcca may be, for example, substantially 3.3V.

Input buffer circuit 100 depicted in FIG. 1 may provide on node idataout a data signal to a core-logic unit (not shown), which in turn may be in communication with another input/output unit to produce another signal, for example, a high voltage output signal, such as an audio output signal. The input buffer circuit 100 may have a buffer switching sub-circuit 118 (V buf-generator) connected to Vcca 114 and Vcc 116 to generate a buffer voltage Vbuf, and a sub-circuit 120 (V gate-generator) to generate a gate voltage Vgate. A data input buffer sub-circuit 112 (inbuf) may receive voltages Vbuf, Vgate, and Vcc 116, and the input signal 115 (pad), and produce an output data signal having a determinate output level, even when the voltage to the unit, Vcca, is turned off or grounded. Signal biasgaten 113 may be an enable signal, such that when biasgaten 113 is asserted, Vbuf and Vgate generation is possible during “normal operation” as described below. Accordingly, when biasgaten 113 is de-asserted, the Vbuf and Vgate generation during normal operation is disabled. It will be noted that biasgaten 113 does not affect generation of Vbuf and Vgate when Vcca is grounded.

Sub-circuit 120 may generate gate voltage Vgate. Gate voltage Vgate may be used in data input buffer sub-circuit 112, explained in further detail below.

Buffer switching sub-circuit 118 may produce a buffer voltage Vbuf to be used by data input buffer sub-circuit 112. According to embodiments of the invention, buffer voltage Vbuf may have a determinate logic value even when Vcca is grounded.

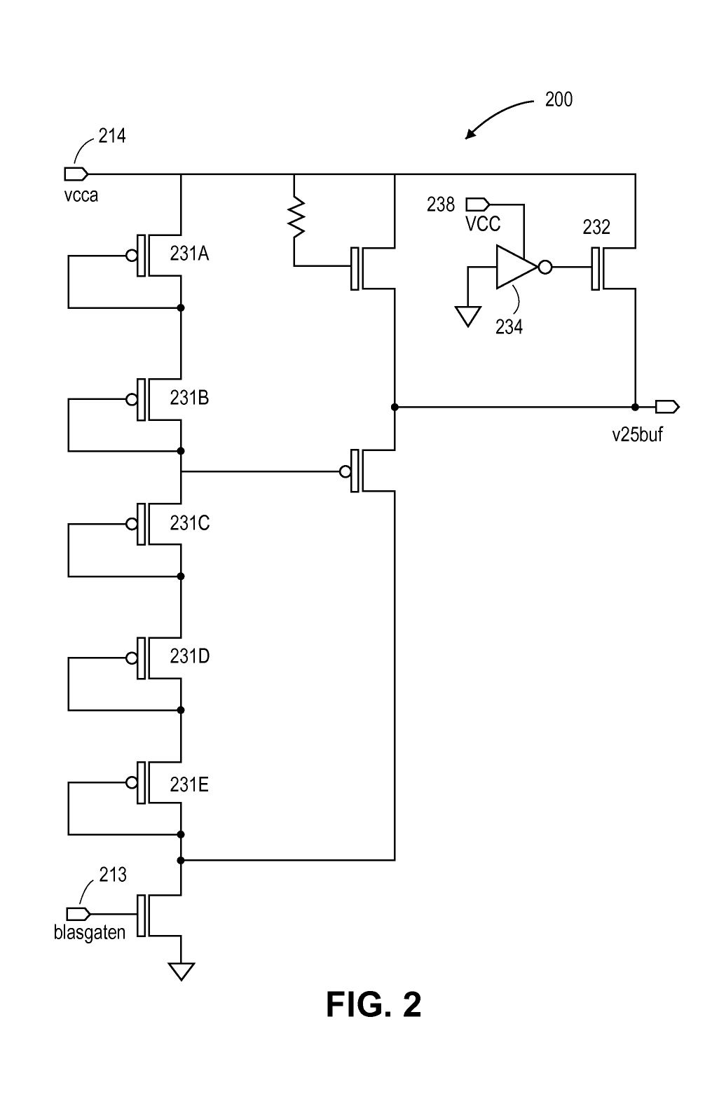

Reference is made to FIG. 2, which depicts a sub-circuit 200 according to embodiments of the present invention that may be used to generate Vbuf. In some embodiments of the invention, the sub-circuit 200 may correspond to buffer switching sub-circuit 118 in FIG. 1. In some embodiments of the invention, a high voltage on Vbuf may typically be less than Vcca. In some embodiments of the invention, Vbuf may be greater than Vcc. In some embodiments of the invention, Vbuf may be, for example, substantially 2.5V.

The sub-circuit 200 may generate Vbuf, for example, substantially 2.5V, based on receiving Vcca at node 214 and Vcc at node 238. In an embodiment of the invention, a switching circuit may be used to allow normal operation when Vcca is, for example, substantially 3.3V, and to clamp Vbuf to substantially 0V when Vcca is grounded. Sub-circuit 200 may receive signal input biasgaten 213 to bias a transistor (which typically includes gate, source and drain connectors) 230, thereby to obtain the 2.5V voltage, as described herein.

In an embodiment of the invention, when Vcca is high, for example, substantially 3.3V, and Vcc is high, for example, substantially 1.25V, inverter 234 may receive substantially 0V input and produce a high output, for example, substantially 1.25V. Accordingly, switch 232 may have its source at higher voltage, for example, substantially 2.5V, with respect to its gate and hence it may be in turned-off mode. Vbuf may therefore generate a desired output voltage, for example, substantially 2.5V. The level of the voltage may be selected based on the selection of cascaded transistors 231A, 231B, 231C, 231D and 231E, as well as other parameters.

When Vcca is low, for example, substantially 0V, and Vcc is high, for example, substantially 1.25V, inverter 234 may receive substantially 0V input and produce a high output, for example, substantially 1.25V. However, because Vcca is substantially 0V, switch 232 may have its source and drain at a lower voltage, for example, substantially 0V, as compared to its gate, and hence it may be in a turned-on mode, clamping the output of Vbuf to a determinate low voltage, for example, substantially 0V.

It will be recognized that switch 232 may be any suitable high voltage transistor or other switch mechanism, for example, any type of suitable metal oxide semiconductor field effect transistor (MOSFET).

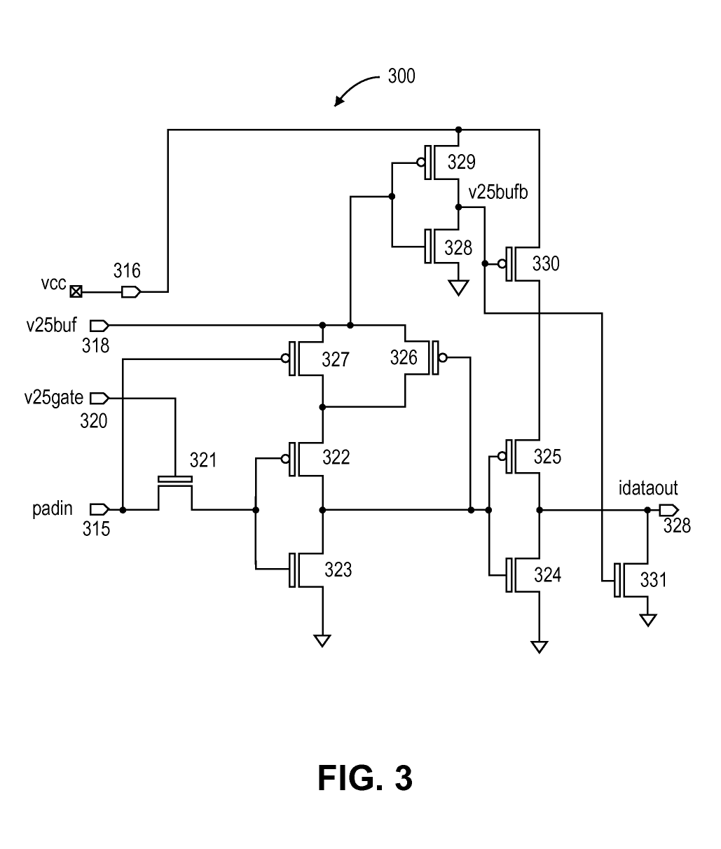

FIG. 3 depicts an input buffer sub-circuit 300 that may correspond to data input buffer sub-circuit 112 in FIG. 1. The inputs to the input buffer sub-circuit 300 may include Vgate 320, Vbuf 318, a logic power voltage Vcc 316, and a data input signal 315. The sub-circuit may produce a data output dataout 328.

Vgate may be used to control a pass transistor 321, which in turn controls the transmission of input data into the input buffer sub-circuit. When input Vgate is provided with an operational voltage, for example, substantially 2.5V, the input data will be transmitted; when Vgate is provided with a low voltage, for example, substantially 0V, the gate terminals of 322 and 323 will be floating.

It will be further recognized that the input signal is then passed through two serially connected data inverters, wherein the first data inverter is generally comprised of transistors 322 and 323, and the second data inverter is generally comprised of transistors 324 and 325. The output from the first data inverter (322, 323) serves as input for the second data inverter (324, 325). During normal operation, e.g., when Vcc and Vcca are high, Vbuf may be a high voltage, for example, substantially 2.5V. Thus, during normal operation, the gate of pull-up transistor 327 follows the data input signal 315 and the gate of pull-up transistor 326 follows an inverted data input signal and thus during normal operation one of pull-up transistors 326 or 327 is operational at any given time, a first power terminal of said pull-up transistors is connected to said Vbuf 318 a second power terminal of said pull-up transistors is connected to provide power to said first data inverter and data on data input node 315 is propagated.

It will further be recognized that Vbuf is provided as an input to an inverting arrangement of transistors 328 and 329. Thus, during normal operation, when Vbuf is high, the gate of transistor 329 is provided with a high voltage, and the transistor does not conduct from source to drain; the gate of transistor 328 is provided with the high voltage and it does conduct from source to drain, providing a low voltage at the gate of 330 and transistor 331. Also, transistor 325 is provided with high voltage during normal operation, as transistor 330 is in ON-mode and presents voltage Vcc (pwrc) to node z, between transistors 325 and 330. Finally, the gate of transistor 331 is provided with a low voltage, and transistor 331, connected at its first power terminal to said data output and to ground at its second power terminal and therefore does not affect the data output, which mirrors the input data when Vgate is a suitable high voltage, and idataout 328 is sent as an input signal to the GMCH core logic unit.

As noted above, when Vcca is turned off or grounded, Vbuf is substantially 0V. In such case, transistor 329 is turned on, and the gate of transistor 331 is provided with a high voltage. When transistor 331 is turned on, the output node 328 is clamped to ground, thereby providing a determinate substantially 0V output to the GMCH core logic unit. It will be recognized that other arrangement are possible falling within the scope of the invention so long as a determinate substantially 0V output is provided to the GMCH core logic unit when Vcca is turned off or grounded.

In some embodiments of the invention, the sub-circuits described may be implemented on die, thereby allowing the power supply on the board to be grounded and hence reducing power consumption, for example, due to leakage or any static current. In some embodiments of the invention, the scheme can be extended to other areas of the die where power supply is isolated, and may be grounded independently if the feature is not used.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

1-2. (canceled)

3. A circuit comprising:
a buffer switching sub-circuit to:
receive a first power supply and a second power supply, wherein the second power supply is independent of the first power supply;
provide a buffer voltage responsive to an activation of the first power supply; and
provide a ground voltage responsive to a deactivation of the first power supply, wherein the buffer switching sub-circuit comprises:
an inverter to be powered by the second power supply, wherein an input of the inverter is connected with a ground voltage; and
a switch to be controlled by an output of the inverter, wherein the switch is a transistor having a gate terminal connected with the output of the inverter, and having one of a source terminal and a drain terminal connected with the first power supply; and
a data input buffer sub-circuit connected with the buffer switching sub-circuit via the other of the source terminal and the drain terminal, having an input node and an output node, the data input buffer sub-circuit is to:
generate at the output node, a data signal provided to the input node responsive to the buffer voltage provided by the buffer switching sub-circuit; and
generate at the output node, a determinate voltage responsive to the ground voltage provided by the buffer switching sub-circuit.

4. The circuit of claim 3, wherein the data input buffer sub-circuit comprises a first and a second data inverter, wherein an output from first data inverter is to be provided as an input to the second data inverter, wherein the input node is to be connected with an input of the first data inverter, and an output of the second data inverter is to be provided to the data signal output node.

5. The circuit of claim 4, wherein a power input node of the second data inverter is to be provided with a high voltage responsive to the buffer voltage provided by the buffer switching sub-circuit, and wherein the power input node of the second data inverter is to be provided with a floating voltage responsive to the ground voltage provided by the buffer switching sub-circuit.

6. The circuit of claim 5, farther comprising two pull-up transistors, a first of the two pull-up transistors having agate terminal connected with the input of the second data inverter and a second of the two pull-up transistors having another gate terminal connected with an inverted signal of the input of the second data inverter, a first power terminal of the first and the second pull-up transistors is to be connected to the second power supply, a second power terminal of the first and the second pull-up transistors is to provide power from the buffer switching sub-circuit to the first data inverter, and a gate controlled based on an output of the buffer switching sub-circuit, wherein the input node of the second data inverter is to be connected to a high voltage responsive to the buffer voltage provided by the buffer switching sub-circuit, and wherein the input node of the second data inverter is to be floating responsive to the ground voltage provided by the buffer switching sub-circuit.

7. The circuit of claim 6, further comprising an output control switch having a first power terminal connected to the output node and a second power terminal being grounded, wherein a gate of the output control switch is to provide a grounded voltage at the output node responsive to the ground voltage provided by the buffer switching sub-circuit.

8. The circuit of claim 1, wherein the first power supply is higher than the second power supply.

9. The circuit of claim 8, wherein the first power supply is substantially 3.3 Volts, and wherein the second power supply is substantially 1.25 Volts.

10. The circuit of claim 9, wherein the buffer voltage is substantially 2.5 Volts.

11. A method comprising:
receiving a first power supply and a second power supply, wherein the second power supply is independent of the first power supply;
providing a buffer voltage responsive to an activation of the first power supply;
providing a ground voltage responsive to a deactivation of the first power supply;
generating at an output node, a data signal provided to an input node responsive to the buffer voltage provided by the buffer switching sub-circuit; and
generating at the output node, a determinate voltage responsive to the ground voltage provided by the buffer switching sub-circuit.
